(19) United States
(12) Patent Application Publication
(10) Pub. No.: US 2014/0151216 A1
(43) Pub. Date: Jun. 5, 2014

(54) Sputtering Apparatus and Method of Manufacturing Display Substrate Using the Same

(71) Applicant: SAMSUNG DISPLAY CO., LTD., Yongin-City (KR)

(72) Inventors: Sang-Woo Sohn, Yongin-Si (KR); Hyung-Jun Kim, Yongin-si (KR)

(73) Assignee: SAMSUNG DISPLAY CO., LTD., Yongin-City (KR)

(21) Appl. No.: 13/900,231

(22) Filed: May 22, 2013

(30) Foreign Application Priority Data
Dec. 3, 2012 (KR) 10-2012-0138996

(51) Int. Cl. H01L 21/02

(52) U.S. Cl. CPC H01L 21/02518
USPC 204/192.1; 204/298.12; 204/298.13

(57) ABSTRACT

A sputtering apparatus includes a chamber. A substrate supporting part is disposed in the chamber. A plurality of targets face the substrate supporting part. A target supporting part is disposed under each of the targets to hold the target. A first ground part is disposed between two target supporting parts adjacent to each other and includes a cover separable therefrom. A second ground part is disposed between two target supporting parts adjacent to each other, except for where the first ground part is disposed.

This application claims priority to Korean Patent Application No. 10-2012-0138996, filed on Dec. 3, 2012, the entire contents of which are incorporated by reference herein in its entirety.

### TECHNICAL FIELD

Exemplary embodiments of the invention relate to a sputtering apparatus, and more particularly, to a sputtering apparatus and a method of manufacturing a display substrate using the sputtering apparatus.

### DISCUSSION OF THE RELATED ART

Generally, a liquid crystal display (LCD) device has various characteristics such as being thin, being lightweight, having low power consumption, etc. Thus, LCD devices have been widely used in computer monitors, notebook computer displays, cellular telephones, etc. The LCD device includes an LCD panel displaying an image by manipulating an optical transmissivity of liquid crystal within the LCD device and a backlight assembly disposed under the LCD panel to provide light to the LCD panel. The LCD panel includes a substrate having a thin film formed thereon.

The thin film may be formed by a sputtering process. According to the sputtering process, plasma, which includes target ions from a target disposed in a chamber, is generated. The substrate is then exposed to the plasma so that deposition material is deposited on the substrate.

As the size of LCD devices have increases, the substrate of the LCD display has also increased in size. Thus, the size of the sputtering target has increased accordingly. Rather than using a single larger target, a plurality of divided targets may be used. However, it may be difficult to ensure thin film uniformity on the portion of the substrate that corresponds to the region where the multiple divided targets meet each other. Thus, problems with an uneven thickness of the thin film and problems with spot or stains corresponding to the portion between the targets may be caused.

### SUMMARY

One or more exemplary embodiment of the invention provides a sputtering apparatus capable of forming a thin film having uniform thickness and reduced irregularity.

One or more exemplary embodiments of the invention also provide method of manufacturing a display substrate using the sputtering apparatus.

According to an exemplary embodiment of the invention, a sputtering apparatus includes a chamber. A substrate supporting part is disposed in the chamber. A plurality of targets face the substrate supporting part. A target supporting part is disposed under each of the targets to hold the target. A first ground part is disposed between two target supporting parts adjacent to each other. The first ground part comprises a cover that is separable therefrom. A second ground part is disposed between two target supporting parts adjacent to each other, except for where the first ground part is disposed.

In an exemplary embodiment, the first ground part may include a base plate extending along a longitudinal direction of the target. A wall extends perpendicular to the base plate from the base plate.

In an exemplary embodiment, the cover of the first ground part may include a cover body disposed on the wall, and a cover protrusion protruding from the cover body. The cover protrusion may overlap a portion of the target adjacent to the first ground part.

In an exemplary embodiment, the cover body of the cover may have a fixing groove combined with the wall.

In an exemplary embodiment, a first combining portion may be formed at the wall of the first ground part. A second combining portion may be formed at the cover body of the cover. The cover may be fixed to the wall by a combination of the first combining portion and the second combining portion.

In an exemplary embodiment, the cover body may extend between two targets adjacent to each other and may also extend between two target supporting parts adjacent to each other.

In an exemplary embodiment, the second ground part may include a base plate extending plate extending along a longitudinal direction of the target, and a wall extending perpendicular to the base plate and extending from the base plate. The base plate and the wall of the second ground part may have a shape substantially the same as the base plate and the wall of the first ground part.

In an exemplary embodiment, a first combining portion may be formed at the wall. A second combining portion may be formed at the cover. The first combining portion and second combining portion may be combined together. A third combining portion may be formed at the second ground part. The second ground part may have substantially the same shape of the first ground part excluding the cover.

In an exemplary embodiment, the sputtering apparatus may further include an insulation element disposed between the first or second ground part and the target supporting part insulating the first or second ground part from the target supporting part.

In an exemplary embodiment, the sputtering apparatus may further include a mask disposed between the target and the target supporting part and defining a sputtering area.

In an exemplary embodiment, the target may include an oxide semiconductor material.

In an exemplary embodiment, the oxide semiconductor material may include zinc oxide (ZnO), zinc tin oxide (ZTO), zinc indium oxide (ZIO), indium oxide (InO), titanium oxide (TiO), indium gallium zinc oxide (IGZO), or indium zinc tin oxide (IZTO).

In an exemplary embodiment, a substrate may be held on the substrate supporting part. A thin film may be formed on the substrate by deposition of a deposition material that includes in the target. A cutting line may be formed on the substrate. The cutting line may correspond to the first ground part.

In an exemplary embodiment, the first ground part may be disposed between two target supporting parts. The two target supporting parts may be disposed at a center of the sputtering apparatus.

In an exemplary embodiment, the sputtering apparatus includes a third ground part having a shape substantially the same as the first ground part, and a fourth ground part having a shape substantially the same as the first ground part. The third ground part may be spaced apart form the first ground part by at least two targets. The fourth ground part may be spaced apart form the first ground part by at least two targets.

In an exemplary embodiment, a substrate may be held on the substrate supporting part. A thin film may be formed on the substrate by deposition of a deposition material that includes in the target. Cutting lines may be formed on the substrate. The cutting lines may correspond to the first, third and fourth ground parts, respectively.

In an exemplary embodiment, the number of the targets may be 14. The first ground part may be disposed between those of the targets that are disposed at a center. The number of the second ground parts may be 12.

In an exemplary embodiment, a width of the target supporting part may be substantially the same as a width of the target.

According to an exemplary embodiment of the invention, a method of manufacturing a display substrate includes forming a thin film on a substrate using a sputtering apparatus, and cutting a cutting line of the substrate. The cutting line corresponds to the first ground part. The sputtering apparatus includes a chamber. A substrate supporting part is disposed in the chamber. A plurality of targets face the substrate supporting part. A target supporting part is disposed under each of the targets to hold the target. A first ground part is disposed between two target supporting parts adjacent to each other and comprising a cover separable therefrom. A second ground part is disposed between two target supporting parts adjacent to each other, except for where the first ground part is disposed.

In an exemplary embodiment, the thin film may include an oxide semiconductor material.

According to an exemplary embodiment of the present invention, the sputtering apparatus includes a first ground part including a cover having T-shape and a second ground part, so that the sputtering apparatus may maintain a potential to generate plasma, and remove unwanted particles during sputtering process. Thus, the unwanted particles may be deposited on a surface of the cover, and the cover may be easily separated from a wall of the first ground part so that the cover may be washed.

In addition, a plurality of display substrates is formed by cutting a cutting line of the substrate. The cutting line corresponds to the first ground part. Spots or stains may be formed on a portion of the substrate to which the first ground part corresponds. However, the substrate may be cut along the cutting line, so that quality of the display substrate may be maintained.

In addition, when the width of the target is substantially the same as the width of the target supporting part, the size of the target may be maximized so that the thin film may be uniform. Thus, a distance between the target supporting parts adjacent to each other may be minimized, so that a portion of the thin film to which a portion between the targets corresponds, may be minimized. Thus, thickness of the thin film may be uniform.

In addition, the cover body of the cover may be disposed between two target supporting parts adjacent to each other, as well as between two targets adjacent to each other. Thus, the width of the cover may be minimized, so that thickness of the thin film may be uniform.

In addition, the second ground part may be substantially the same as the base plate, the wall and the first combining portion of the first ground part. Thus, the cover of the first ground part may be combined with the second ground part, as desired. Therefore, the position of the cover may be changed according to the position of the cutting line.

### BRIEF DESCRIPTION OF THE DRAWINGS

The above and other features of the invention will become more apparent by describing in detail exemplary embodiments thereof with reference to the accompanying drawings, in which:

FIG. 1 is a cross-sectional view illustrating a sputtering apparatus according to an exemplary embodiment of the invention;

FIG. 2 is a perspective view illustrating a first ground part of FIG. 1;

FIG. 3 is a perspective view illustrating a second ground part of FIG. 1;

FIG. 4 is a cross-sectional view illustrating a sputtering apparatus according to an exemplary embodiment of the invention;

FIG. 5 a cross-sectional view illustrating a sputtering apparatus according to an exemplary embodiment of the invention;

FIG. 6 is a enlarged cross-sectional view of part of a first ground part of FIG. 5;

FIG. 7 is a perspective view illustrating a first ground part of FIG. 5;

FIG. 8 is a perspective view illustrating a second ground part of FIG. 5;

FIG. 9 is a plan view illustrating a sputtering apparatus according to an exemplary embodiment of the invention; and

FIG. 10 is a plan view of a substrate of FIG. 9 illustrating a cutting line.

### DETAILED DESCRIPTION OF EXAMPLE EMBODIMENTS

It will be understood that when an element or layer is referred to as being “on” or “connected to” another element or layer, the element or layer can be directly on or connected to another element or layer or intervening elements or layers. Like numbers may refer to like elements throughout. As used herein, the term “and/or” includes any and all combinations of one or more of the associated listed items.

Hereinafter, the invention will be explained in detail with reference to the accompanying drawings.

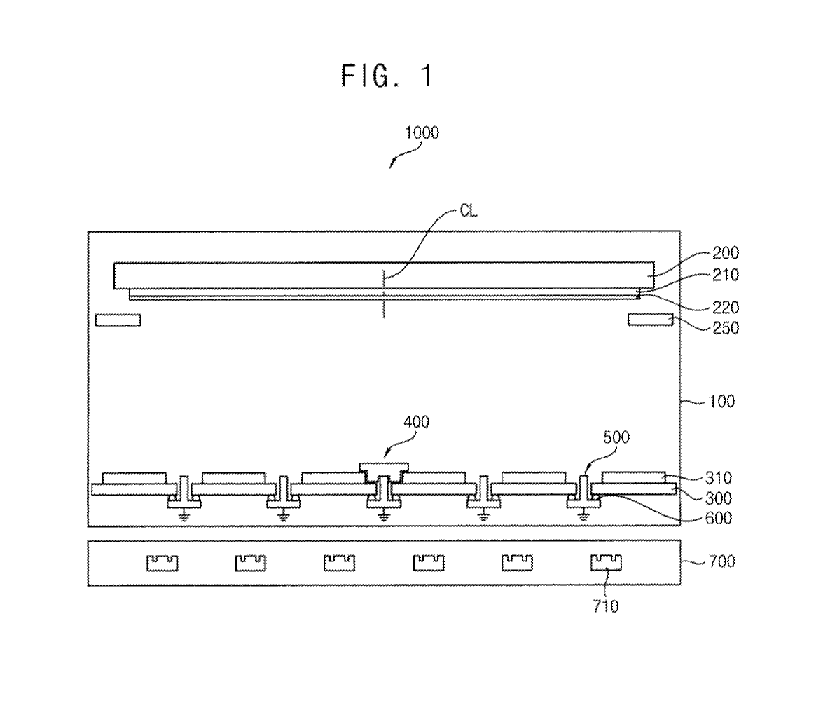

FIG. 1 is a cross-sectional view illustrating a sputtering apparatus according to an exemplary embodiment of the invention.

Referring to FIG. 1, the sputtering apparatus 1000 includes a chamber 100, a substrate supporting part 200, a target supporting part 300, a target 310, a first ground part 400, a second ground part 500 and a magnetic assembly 700.

The chamber 100 provides a space to form a thin film 220 on a substrate 210 by a sputtering process. For the sputtering process, the inside of the chamber 100 may be maintained at a vacuum or negative pressure. Alternatively, or additionally, the chamber 100 may be filled with a noble gas. For example, the noble gas argon (Ar), helium (He), neon (Ne), krypton (Kr) or xenon (Xe). For example, a pressure of argon (Ar) in the chamber 100 may be about 1 to 100 mTorr.

The substrate supporting part 200 is disposed inside of the chamber 100 and may hold the substrate 210. For example, the substrate supporting part 200 may hold the substrate 210 through vacuum absorption. In addition, the substrate supporting part 200 may hold the substrate 210 using a clip disposed around boundaries of the substrate 210. In addition, the substrate supporting part 200 may hold the substrate 210 through a sliding combination.

The substrate 210 may be a display substrate of a liquid crystal display panel. The thin film 220 formed on the substrate 210 may be a wiring of the display substrate. In addition, or alternatively, the thin film 220 may be an oxide semiconductor layer of the display substrate. The oxide semiconductor layer includes an oxide semiconductor. For example, the oxide semiconductor may include zinc oxide (ZnO), zinc tin oxide (ZTO), zinc indium oxide (ZIO), indium oxide (InO), titanium oxide (TiO), indium gallium zinc oxide (IGZO), or indium zinc tin oxide (IZTO).

The target supporting part 300 is disposed in the chamber 100 and faces the substrate supporting part 200. A plurality of target supporting parts may be disposed in the chamber 100. In an enlarged display substrate, the target 310 becomes bigger, and a plurality of the targets having a greater number of targets may be disposed in consideration of a size of the substrate 210. Therefore sputtering efficiency and management efficiency may be increased. Accordingly, a plurality of target supporting parts 300 may be disposed. The target supporting parts 300 are spaced apart from each other and disposed side by side.

The target 310 is disposed on the target supporting part 300, and faces the substrate 210 that is held on the substrate supporting part 200. The target 310 may consist of a deposition material which is deposited on the substrate 210. The target 310 may include an oxide semiconductor as the deposition material. For example, the oxide semiconductor may include zinc oxide (ZnO), zinc tin oxide (ZTO), zinc indium oxide (ZIO), indium oxide (InO), titanium oxide (TiO), indium gallium zinc oxide (IGZO), or indium zinc tin oxide (IZTO).

A plurality of targets 310 may be disposed according to the size of the substrate 210. The targets are spaced apart from each other and are disposed side by side. The target 310 is consumed by the sputtering process, so that the target 310 may be replaceable. The target 310 may have a size smaller than that of the target supporting part 300 in a plan view. Thus, the target 310 need not be disposed on a boundary of the target supporting part 300.

A plasma power may be applied to the target 310 through the target supporting part 300. The plasma power includes an RF voltage. The substrate supporting part 200 may include conductive material. The substrate supporting part 200 may be electrically connected to the target 310, and the RE voltage may be applied thereto. In addition, the substrate supporting part 200 may be electrically connected to an external ground terminal and a reference voltage of the RF voltage may be set.

The RF voltage may cause a plasma discharge by being applied to the chamber 100 through the substrate supporting part 200 and the target supporting part 300.

A mask 250 may be disposed between the substrate 210 and the target 310, to define a shape of the deposition material which is deposited on the substrate 210. For example, the mask 250 may expose a portion of the substrate 210 on which the thin film 220 is formed.

The first ground part 400 or the second ground part 500 is disposed between the target supporting parts 300 (or the targets 300) adjacent to each other.

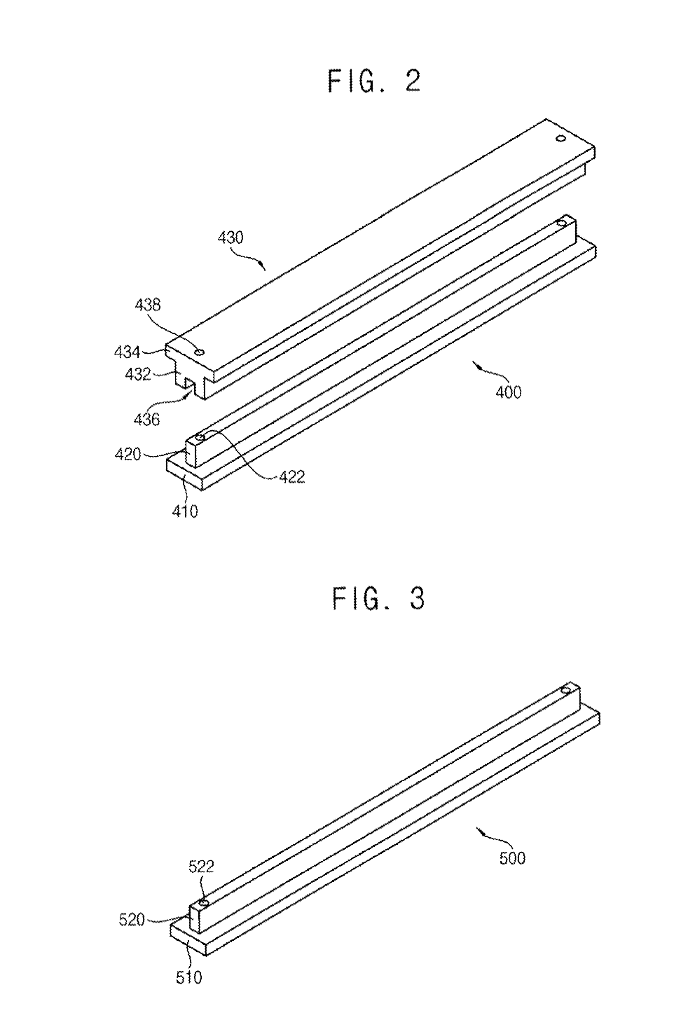

The first ground part 400 is disposed between the two target supporting parts 300 which are disposed at a center of the sputtering apparatus. Thus, the first ground part 400 is disposed at a center of an array of the targets 310. The first ground part 400 is spaced apart from the target supporting part 300 and the target 310 which are adjacent to the first ground part 400. An insulation element 600 may be disposed between the target supporting part 300 and the first ground part 400 configured to prevent from being short to the target supporting part 300. Detailed explanation about the first ground part 400 will be mentioned at FIG. 2.

The insulation element 600 may include a resin having thermal resistance. The insulation element 600 may be a plurality of protrusions disposed on the first ground part 400. In addition, the insulation element 600 may have a plate shape.

The second ground part 500 is disposed between the target supporting parts 300, except for where the first ground part 400 is disposed. The second ground part 500 is spaced apart from the target supporting part 300 and the target 310. An insulation element 600 may be disposed between the target supporting part 300 and the second ground part 500 and may be configured to prevent the formation of a short circuit to the target supporting part 300. A detailed explanation about the second ground part 500 will be provided below with reference to FIG. 3.

The insulation element 600 is substantially the same as the insulation element disposed between the first ground part 400 and the target supporting part 300.

The first and second ground parts 400 and 500 prevent the targets 310 and the target supporting part 310 from shorting. In addition, first and second ground parts 400 and 500 may be connected to an external ground terminal to maintain a potential for forming plasma. In addition, the first and second ground parts 400 and 500 may be connected to the external ground terminal to ground unwanted electrons accumulated as a result of the plasma discharge.

The magnetic assembly 700 includes magnetic elements 710 disposed under each of the target 310. The magnetic elements 710 establish a magnetic field between the substrate 220 and the target 310 and are configured to prevent the breakaway of electrons as a result of the plasma discharge. The magnetic elements 710 may uniformly move to change the magnetic field.

The substrate 210 on which the thin film 220 is formed, may be turned into a display substrate through a plurality of processes. Thereafter, the substrate 210 may be cut into a specific size. For example, the substrate 210 may be cut along a cutting line CL which is formed at a center of the substrate 210. The cutting line CL may correspond to a portion on which the first ground part 400 is disposed.

RF voltage is applied to the target 310. Secondary electrons may accumulate at a surface of the target 310 as a result of the RF voltage. The secondary electrons may crash with particles of the noble gas which is injected into the chamber 100. The secondary electrons may exchange momentum to the particle of the noble gas, so that the plasma is formed from the target 310. Breakaway of the secondary electrons may be prevented by the magnetic assembly 700.

FIG. 2 is a perspective view illustrating a first ground part of FIG. 1.

Referring to FIG. 2, the first ground part 400 includes a base plate 410, a wall 420 and a cover 430.

The base plate 410 extends along a longitudinal direction of a target (320 of FIG. 1). The wall 420 extends from the base plate 410 in a direction perpendicular to the base plate 410. The base plate 410 and the wall 420 may include a metal material which has a relatively high corrosion resistance and a relatively high thermo resistance. For example, the base plate 410 and the wall 420 may include stainless steel. Although not shown in figures, the wall 420 may be divided into a plurality of walls along a longitudinal direction. The wall 420 may be fixed to the base plate 410 by a bolt. In addition, the wall 420 may be fixed to the base plate 410 by a welding or hook assembly.

The cover 430 includes a cover body 432 and a cover protrusion 434. The cover 430 is disposed on the wall 420. The cover protrusion 434 protrudes from the cover body 432, and overlaps with a boundary of the target (310 of FIG. 1).

A fixing groove 436 is formed under the cover body 432 of the cover 430 and fixes the cover 430 on the wall 420. The wall 420 is inserted into the fixing groove 436, so that the cover 430 may be fixed on the wall 420. The cover 430 may be combined to the wall 420 in a various ways. For example, the cover 430 and the wall 420 may be combined through screw (not shown) and screw hole 438 and 422 formed on the cover 430 and the wall 420, respectively. In addition, the cover 430 may be fixed to the wall 420 by hook assembly or slide assembly.

With the sputtering process, unwanted particles may be deposited on the cover 430. The cover 430 may be easily separated form the wall 420, so that the cover 430 may be washable. When the deposition material includes the oxide semiconductor, the unwanted particles, which are unnecessary to form the thin film 220, may be mostly deposited on the cover 430. The cover 430 includes the cover protrusion 434 overlapping with a boundary of the target 310, so that the unwanted particles may be mostly deposited on a surface of the cover protrusion 434. For example, when the target 310 includes the oxide semiconductor, the unwanted particles may be deposited on a boundary of the substrate 210 corresponding to the boundary of the target 310. In this case, the cover 430 may prevent the unwanted particles from being deposited on the substrate 210.

In addition, an upper width of the cover 430 is wider than that of the second ground part 500, so that the sputtering apparatus may better maintain the potential for forming plasma.

FIG. 3 is a perspective view illustrating a second ground part of FIG. 1.

Referring to FIG. 3, the second ground part 500 includes a base plate 510, and a wall 520.

The base plate 510 extends along a longitudinal direction of a target (320 of FIG. 1). The wall 520 extends perpendicular to the base plate 510 on the base plate 510. The base plate 510 and the wall 520 may include a metal material which has a relatively high corrosion resistance and a relatively high thermo resistance. For example, the base plate 510 and the wall 520 may include stainless steel. Although not shown in figures, the wall 520 may be divided into a plurality of walls along a longitudinal direction. The wall 520 may be fixed to the base plate 510 by a bolt. In addition, the wall 420 may be fixed to the base plate 510 by a welding or hook assembly.

A screw hole 522 may be formed on the wall 520 of the second ground part 500. Thus, the base plate 510 and the wall 420 may be substantially the same as the base plate 410 and the wall 420 of the first ground part 400. Thus, the cover 430 of the first ground part 400 may be combined to the second ground part 500.

Referring again to FIGS. 1 to 3, the sputtering apparatus 1000 includes the first ground part 400 including the cover 430 having T-shape and the second ground part 500. A plurality of display substrates is formed by cutting the substrate 210 along the cutting line CL of the substrate 210 which corresponds to the first ground part 400. Spots or stains may be formed on a portion of the substrate 210 to which the first ground part 400 corresponds. However, the substrate 210 may be cut along the cutting line CL, so that quality of the display substrate may be maintained.

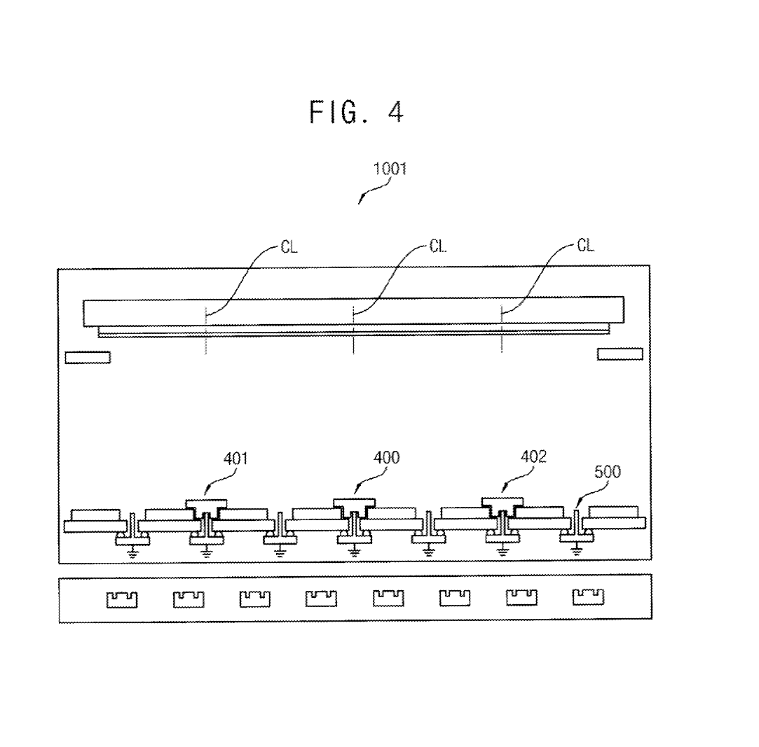

FIG. 4 is a cross-sectional view illustrating a sputtering apparatus according to an exemplary embodiment of the invention.

Referring to FIG. 4, the sputtering apparatus 1001 is substantially the same as a sputtering apparatus 1000 of FIG. 1, except for a third ground part 401 and a firth ground part 402. Thus, any further detailed descriptions concerning the same elements as those occurring in FIG. 1 will be omitted.

A first ground part 400, a second ground part 500, the third ground part 401 or the fourth ground part 402 is disposed between target supporting parts 300 (or targets 300) adjacent to each other.

The first ground part 400 includes a cover (430 of FIG. 2). The first ground part 400 is disposed between the two target supporting parts 300 which are disposed at a center of the sputtering apparatus. The first ground part 400 is substantially the same as the first ground part 400 of FIGS. 1 and 2, so that any further detailed descriptions concerning the same elements will be omitted.

The third ground part 401 includes a cover (430 of FIG. 2). The third ground part 401 is spaced apart from the first ground part 400 by at least two targets 310. The third ground part 401 may have a shape substantially the same as the first ground part 400, so that any further detailed descriptions concerning the same elements will be omitted.

The fourth ground part 402 includes a cover (430 of FIG. 2). The fourth ground part 402 is spaced apart from the first ground part 400 by at least two targets 310. The fourth ground part 402 may have a shape substantially the same as the first ground part 400, so that any further detailed descriptions concerning the same elements will be omitted.

The second ground part 500 is disposed where the first ground part 400, the third ground part 401 or the fourth ground part 402 is not disposed. The second ground part 500 is substantially the same as the second ground part 500 of FIGS. 1 to 3, so that any further detailed descriptions concerning the same elements will be omitted.

A plurality of display substrates is formed by cutting the substrate 210 along a cutting line CL of the substrate 210 which corresponds to the first ground part 400, the third ground part 401 and the fourth ground part 402. Spots or stains may be formed on a portion of the substrate 210 to which the first ground part 400, the third ground part 401 and the fourth ground part 402 correspond. However, the substrate 210 may be cut along the cutting line CL, so that quality of the display substrate may be maintained.

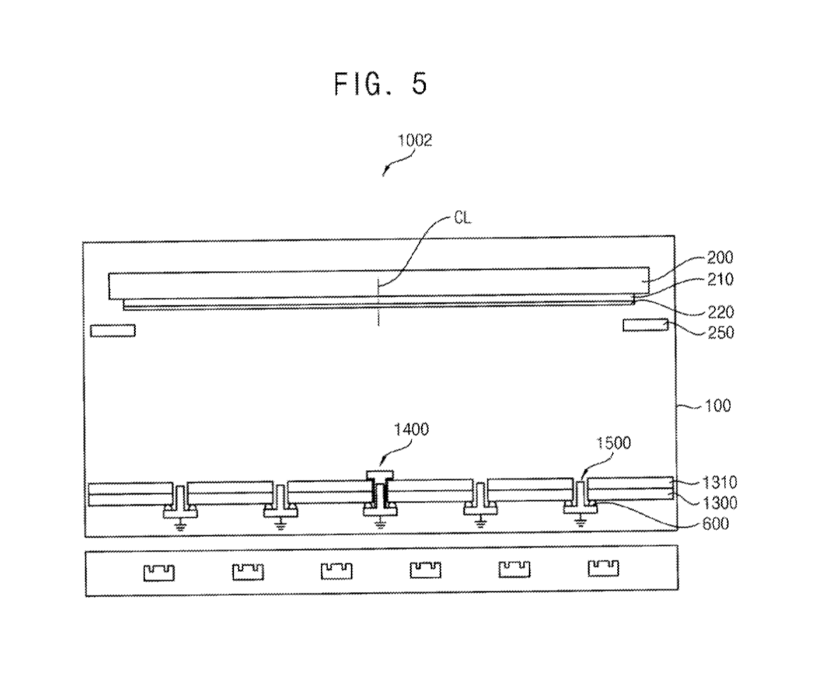

FIG. 5 a cross-sectional view illustrating a sputtering apparatus according to an exemplary embodiment of the invention.

Referring to FIG. 5, the sputtering apparatus 1002 is substantially the same as a sputtering apparatus 1000 of FIG. 1, except for a target supporting part 1300, a target 1310, and a first ground part 1400. Thus, any further detailed descriptions concerning the same elements will be omitted.

The target supporting part 1300 is disposed facing a substrate supporting part in the chamber 100. A plurality of the target supporting parts 1300 may be disposed in the chamber 100. The target supporting parts 1300 are spaced apart from each other and are disposed side by side.

The target 1310 is disposed on the target supporting part 1300, and faces the substrate which is held on the substrate supporting part. The target 1310 may include a deposition material which is deposited on the substrate. Thus, the deposition material is deposited on the substrate to form a thin film. Each od a plurality of the targets 1310 are spaced apart from each other and are disposed side by side. The target 1310 may have a size substantially the same as that of the target supporting part 1300 in a plan view. A width of the target 1310 is substantially the same as a width of the target supporting part 1300, so that the size of the target 1310 may be enlarged while the thin film is uniform. Thus, a distance between the target supporting parts 1300 adjacent to each other may be minimized, so that a portion of the thin film to which a portion between the targets 1300 corresponds, may be minimized. Thus, the thickness of the thin film may be uniform.

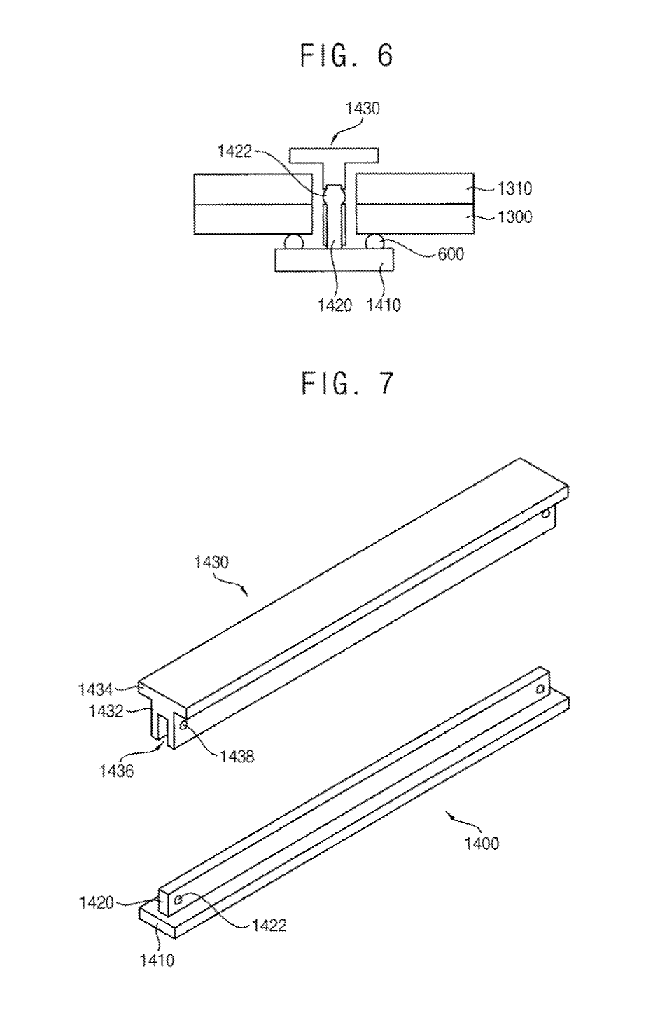

The first ground part 1400 is disposed between the two target supporting parts 1300 which are disposed at a center of the sputtering apparatus. Thus, the first ground part 1400 is disposed at a center of an array of the targets 1310. An insulation element 600 may be disposed between the target supporting part 1300 and the first ground part 1400 and may be configured to prevent the target supporting part 1300 from shorting. A detailed explanation of the first ground part 1400 is provided below with reference to FIGS. 6 and 7.

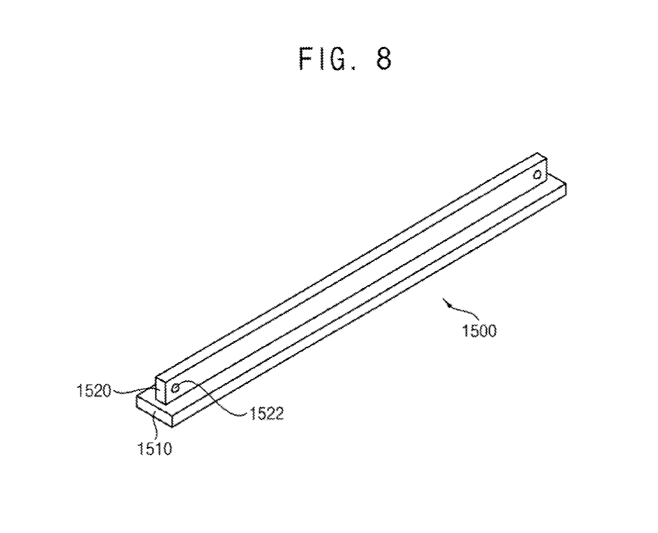

The second ground part 1500 is disposed between the target supporting parts 1300, except for where the first ground part 1400 is disposed. An insulation element 600 may be disposed between the target supporting part 1300 and the second ground part 1500 and may be configured to prevent the second ground part 1300 from being shorted to the target supporting part 1300. A detailed explanation of the second ground part 1500 is provided below with respect to FIG. 8.

FIG. 6 is an enlarged cross-sectional view of part of a first ground part of FIG. 5. FIG. 7 is a perspective view illustrating a first ground part of FIG. 5.

Referring to FIGS. 6 and 7, the first ground part 1400 includes a base plate 1410, a wall 1420 and a cover 1430. The first ground part 1400 is substantially the same as the first ground part 400 of FIG. 2, except for a first combining portion 1422, a second combining portion 1438 and a fixing groove 1436. Thus, any further detailed descriptions concerning the same elements will be omitted.

The base plate 1410 extends along a longitudinal direction of a target. The wall 1420 extends perpendicular to the base plate 1410 from the base plate 1410. The first combining portion 1422 is formed on the wall 1420. The first combining portion 1422 is combined with the second combining portion 1438 of the cover 1430, so that the cover 1430 may be fixed on the wall 1420. For example, the first combining portion 1422 may be a protrusion formed on a side of the wall 1420, and the second combining portion 1438 may be a hole formed on a cover body 1432 of the cover 1430.

The cover 1430 includes a cover body 1432 and a cover protrusion 1434. The cover 430 is disposed on the wall 420. The cover protrusion 1434 protrudes from the cover body 1432, and overlaps with a boundary of the target.

The fixing groove 1436 is formed under the cover body 1432 of the cover 1430 to fix the cover 1430 on the wall 1420. The wall 1420 is inserted into the fixing groove 1436, so that the cover 1430 may be fixed on the wall 1420.

The cover body 1432 of the cover 1430 may be disposed between two target supporting parts adjacent to each other, as well as between two targets adjacent to each other, comparing to the cover 430 of FIG. 2. Accordingly, although a thickness of a portion of the cover body 1420, which forms the fixing groove 1436, is relatively small, the fixing groove 1436 may have a sufficient depth, so that the cover 1430 may be firmly fixed on the wall 1420.

A second combining part 1438 may be formed on the cover body 1432 of the cover 1430. The second combining part 1438 is combined with the first combining part 1422 to combine the cover 1430 with the wall 1420. For example, the first combining part 1422 may be a protrusion formed on a side of the wall 1420, and the second combining part 1438 may be a hole formed through the cover body 1432 of the cover 1430.

The cover 1430 may be easily separated form the wall 1420, so that the cover 1430 may be washable. When the deposition material includes the oxide semiconductor, the unwanted particles which are unnecessary to form a thin film may be mostly deposited on the cover 1430. The cover 1430 includes the cover protrusion 1434 overlapping with a boundary of the target 1310, so that the unwanted particles may be mostly deposited on a surface of the cover protrusion 1434.

According to an exemplary embodiment, a size of the target may be maximized, and a width of the cover may be minimized, so that the thin film may have a uniform thickness.

FIG. 8 is a perspective view illustrating a second ground part of FIG. 5.

Referring to FIG. 8, the second ground part 1500 includes a base plate 1510 and wall 1520. The second ground part 1500 is substantially the same as the second ground part 500 of FIG. 3, except for a first combining part 1522. Thus, any further detailed descriptions concerning the same elements will be omitted.

The base plate 1510 extends along a longitudinal direction of a target. The wall 1520 extends perpendicular to the base plate 1510 from the base plate 1510. The first combining portion 1522 is formed on the wall 1520. The first combining portion 1522 may be substantially the same as the first combining portion 1422 of the first ground part 1400. Thus, the second ground part 1500 may be substantially the same as the base plate 1410, the wall 1420 and the first combining portion 1422 of the first ground part 1400. Thus, the cover 1430 of the first ground part 1400 may be combined with the second ground part 1500, as desired.

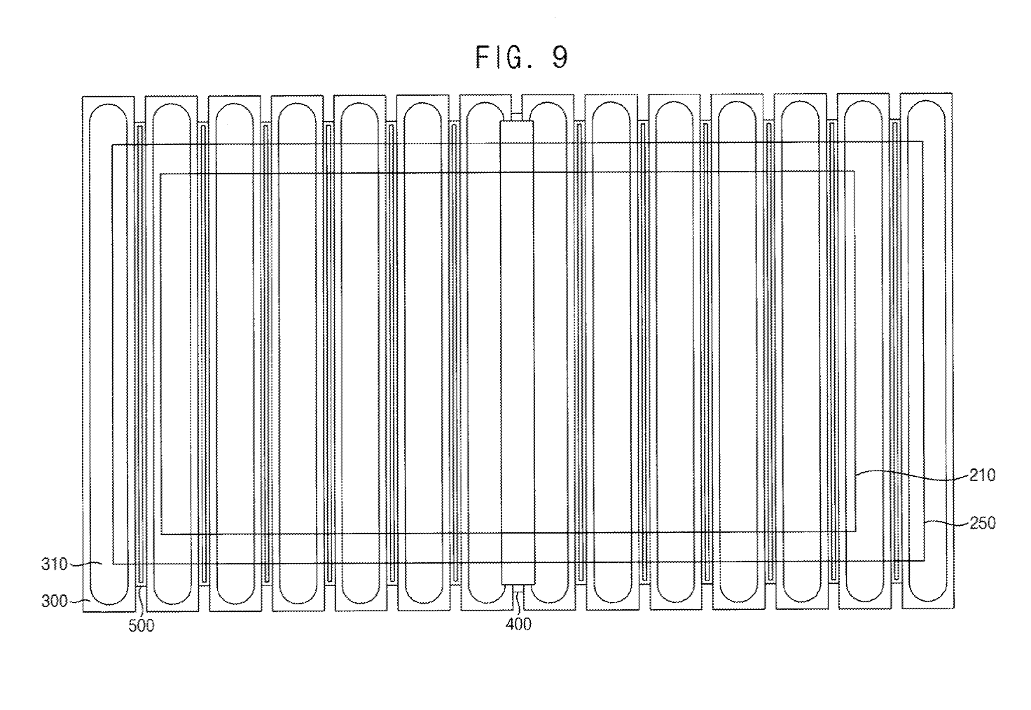

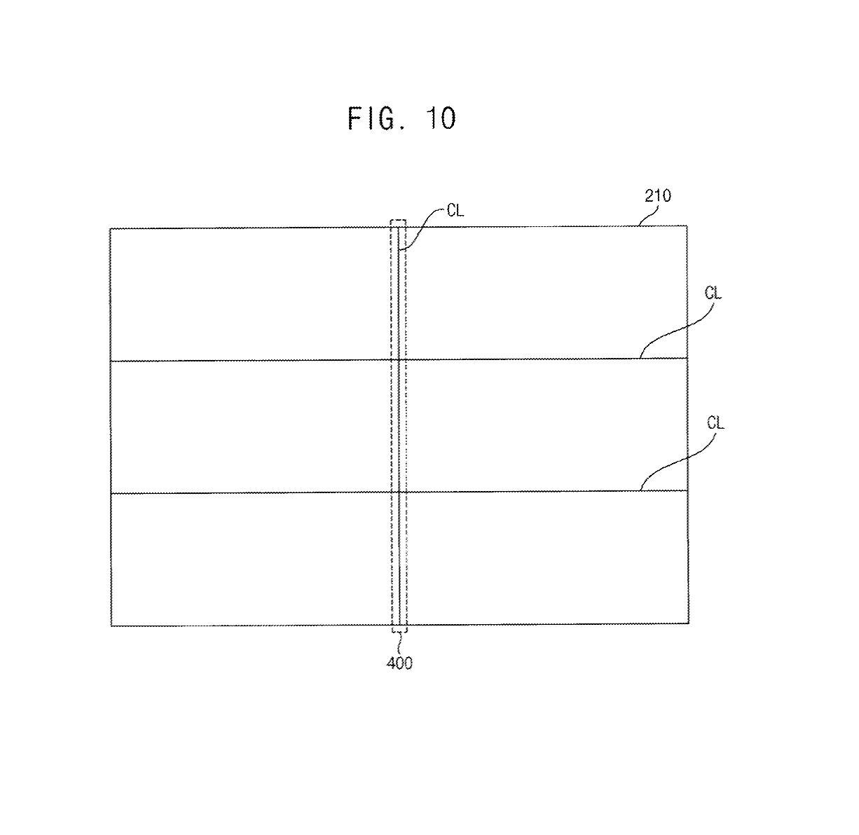

FIG. 9 is a plan view illustrating a sputtering apparatus according to an exemplary embodiment of the invention. FIG. 10 is a plan view of a substrate of FIG. 9 illustrating a cutting line.

Referring to FIGS. 9 and 10, the sputtering apparatus is substantially the same as the sputtering apparatus 1000 of FIG. 1, except for the number of targets 310 and an array of a first ground part 400 and a second ground part 500. Thus, any further detailed descriptions concerning the same elements will be omitted.

A plurality of targets 310 corresponding to a substrate 210 is disposed. Both ends of each of the target 310 may have rounded edges. The targets 310 are spaced apart from each other. The first or ground part 400 or 500 may be disposed between the targets.

A target supporting part 300 is disposed under each of the targets 310. A size of the target supporting part 300 may be the same as or bigger than that of the target 310 in a plan view. The target supporting parts 300 are separated from each other. The first or ground part 400 or 500 may be disposed between the target supporting parts.

The first ground part 400 is disposed between the two target supporting parts 300 which are disposed at a center of the sputtering apparatus. The second ground part 500 is disposed between the target supporting parts 300, except for where the first ground part 400 is disposed.

A mask 250 may determine a shape of the thin film formed on the substrate 210. The mask 250 exposes a portion of the substrate 210 on which the thin film is formed. The mask 250 may have an opening bigger than the substrate 210 in a plan view. The substrate 210 may be disposed in the mask 250 in a plan view.

After the thin film is formed on the substrate 210, the substrate 210 may be cut into a plurality of display substrates. The substrate 210 may be cut along a cutting line CL. At least one of the cutting lines CL may correspond to the first ground part 400. Thus, the cutting line CL may be formed at a portion of the substrate 210 which corresponds to the first ground part 400.

Although one cutting line CL is shown as being disposed corresponding to the first ground part 400, when the sputtering apparatus includes a plurality of the first ground parts 400, a plurality of cutting lines corresponds to each of the first ground parts may be formed.

The cover 430 of the first ground part 400 may remove unwanted particles and maintain plasma potential during the sputtering process. The first ground part 400 overlaps a portion of the target 310, so that thin film formed on the substrate 210 may have spot or stain thereon. According to an exemplary embodiment of the present invention, the cutting line CL is formed at a portion of the substrate 210 which corresponds to the first ground part 400 where spots or stains may form, and the cutting line CL is cut away, so that quality of finished products may be maintained.

Although one first ground part 400 might be disposed only at a center of the targets 310, a plurality of first ground parts may be disposed, and a plurality of cutting lines corresponding to each of the first ground parts may be formed on the substrate 210.

A sputtering apparatus includes a chamber. A substrate supporting part is disposed in the chamber. A plurality of targets face the substrate supporting part. A target supporting part is disposed under each of the targets to hold the target. A first ground part is disposed between two target supporting parts adjacent to each other. The first ground part comprises a cover separable therefrom. A second ground part is disposed between two target supporting parts adjacent to each other, except for where the first ground part is disposed. A method of manufacturing a display substrate may include a step of forming a thin film on a substrate, and a step of cutting a portion corresponding to the first ground part to form the display substrate. The sputtering apparatus may be the sputtering apparatus 100 of FIG. 1.

The thin film may be an oxide semiconductor layer. The oxide semiconductor layer includes an oxide semiconductor. For example, the oxide semiconductor may include zinc oxide (ZnO), zinc tin oxide (ZTO), zinc indium oxide (ZIO), indium oxide (InO), titanium oxide (TiO), indium gallium zinc oxide (IGZO), or indium zinc tin oxide (IZTO).

A portion corresponding to the first ground part is cut away to form the display substrate, so that quality of the display substrate may be maintained.

According to an exemplary embodiment of the present invention, the sputtering apparatus includes a first ground part including a cover having T-shape and a second ground part, so that the sputtering apparatus may maintain potential to generate plasma, and remove unwanted particles during sputtering process. Thus, the unwanted particles may be deposited on a surface of the cover, and the cover may be easily separated from a wall of the first ground part to wash the cover.

In addition, a plurality of display substrates is formed by cutting a cutting line of the substrate. The cutting line corresponds to the first ground part. Spots or stains may be formed on a portion of the substrate to which the first ground part corresponds. However, the substrate may be cut along the cutting line, so that quality of the display substrate may be maintained.

In addition, when a width of the target is substantially the same as a width of the target supporting part, the size of the target may be maximized configured so that the thin film may be uniform. Thus, a distance between the target supporting parts adjacent to each other may be minimized, so that a portion of the thin film to which a portion between the targets corresponds, may be minimized. Thus, thickness of the thin film may be uniform.

In addition, the cover body of the cover may be disposed between two target supporting parts adjacent to each other, as well as between two targets adjacent to each other. Thus, the width of the cover may be minimized, so that thickness of the thin film may be uniform.

In addition, the second ground part may be substantially the same as the base plate, the wall and the first combining portion of the first ground part. Thus, the cover of the first ground part may be combined with the second ground part, as desired. Therefore, position of the cover may be changed according to position of the cutting line.

The foregoing is illustrative of the invention and is not to be construed as limiting thereof. Although a few exemplary embodiments of the invention have been described, those skilled in the art will readily appreciate that many modifications are possible in the exemplary embodiments without materially departing from the novel teachings and advantages of the invention.

What is claimed is:

1. A sputtering apparatus comprising:
a chamber;
a substrate supporting part disposed in the chamber;
a plurality of targets disposed within the chamber and facing the substrate supporting part;
a plurality of target supporting parts, each of the plurality of target supporting parts disposed under a corresponding target of the plurality of targets, the target supporting part configured to hold the plurality of targets;
a first ground part disposed between a first two adjacent target supporting parts of the plurality of target supporting parts, the first ground part comprising a removable cover; and
a plurality of second ground parts, each of which is disposed between adjacent target supporting parts of the plurality of target supporting parts, except for between the first two adjacent target supporting parts where the first ground part is disposed.

2. The sputtering apparatus of claim 1, wherein the first ground part comprises a base plate extending along a longitudinal direction of the target; and
a wall extending perpendicular to the base plate from the base plate.

3. The sputtering apparatus of claim 2, wherein the cover of the first ground part comprises a cover body disposed on the wall, and a cover protrusion protruding from the cover body, the cover protrusion overlapping a portion of a target of the plurality of targets adjacent to the first ground part.

4. The sputtering apparatus of claim 3, wherein the cover body of the cover has a fixing groove combined with the wall.

5. The sputtering apparatus of claim 4, wherein a first combining portion is formed at the wall of the first ground part, a second combining portion is formed at the cover boy of the cover, and the cover is fixed to the wall by combination of the first combining portion and the second combining portion.

6. The sputtering apparatus of claim 4, wherein the cover body extends between a first two adjacent targets adjacent of the plurality of targets that correspond to the first two adjacent target supporting parts.

7. The sputtering apparatus of claim 2, wherein the second ground part comprises a base plate extending plate extending along a longitudinal direction of the target; and
a wall extending perpendicular to the base plate from the base plate, and
wherein the base plate and the wall of the second ground part has a shape substantially the same as the base plate and the wall of the first ground part.

8. The sputtering apparatus of claim 7, wherein a first combining portion is formed at the wall, a second combining portion is formed at the cover, the first combining portion and second combining portion are combined together,
a third combining portion is formed at the second ground part, the second ground part is substantially the same as a shape of the first ground part excluding the cover.

9. The sputtering apparatus of claim 1, further comprising an insulation element disposed between the first or second ground part and the target supporting part to insulate the first or second ground part from the target supporting part.

10. The sputtering apparatus of claim 1, further comprising a mask disposed between the plurality of targets and the plurality of target supporting parts, the mask defining a sputtering area.

11. The sputtering apparatus of claim 1, wherein the plurality of targets comprise an oxide semiconductor material.

12. The sputtering apparatus of claim 11, wherein the oxide semiconductor material comprises zinc oxide (ZnO), zinc tin oxide (ZTO), zinc indium oxide (ZIO), indium oxide (InO), titanium oxide (TiO), indium gallium zinc oxide (IGZO), or indium zinc tin oxide (IZTO).

13. The sputtering apparatus of claim 1, wherein a substrate is held on the substrate supporting part, a thin film is formed on the substrate by deposition of a deposition material that includes in the target, and
a cutting line is formed on the substrate, the cutting line running through a center of the first ground part.

14. The sputtering apparatus of claim 1, wherein the first two target supporting parts are disposed at a center of the sputtering apparatus.

15. The sputtering apparatus of claim 1, further comprising:
a third ground part having a shape substantially the same as the first ground part, the third ground part spaced apart form the first ground part by at least two targets of the plurality of targets, and
a fourth ground part having a shape substantially the same as the first ground part, the fourth ground part spaced apart form the first ground part by at least two targets of the plurality of targets.

16. The sputtering apparatus of claim 15, wherein a substrate is held on the substrate supporting part, a thin film is formed on the substrate by deposition of a deposition material, and
cutting lines are formed on the substrate, the cutting lines correspond to the first, third and fourth ground parts, respectively.

17. The sputtering apparatus of claim 1, wherein the plurality of the targets includes 14 targets, the first the two adjacent targets are centered among the plurality of targets, and there are 12 ground parts within the plurality of second ground parts.

18. The sputtering apparatus of claim 1, wherein the width of the target supporting part is substantially the same as width of each target of the plurality of targets.

19. A method of manufacturing a display substrate, comprising:
forming a thin film on a substrate using a sputtering apparatus, the sputtering apparatus comprising a chamber, a substrate supporting part disposed in the chamber, a plurality of targets facing the substrate supporting part, a target supporting part disposed under each of the plurality of targets, a first ground part disposed between a first two adjacent target supporting parts of the plurality of target supporting parts, the first ground part comprising a removable cover, and a plurality of second ground parts, each of which is disposed between adjacent target supporting parts of the plurality of target supporting parts, except for between the first two adjacent target supporting parts where the first ground part is disposed; and
cutting a cutting line of the substrate, the cutting line running through a center of the first ground part and forming the display substrate.

20. The method of claim 19, wherein the thin film comprises an oxide semiconductor material.
